(19) United States
(12) Patent Application Publication
(10) Pub. No.: US 2015/0014832 A1
(43) Pub. Date: Jan. 15, 2015

(54) Semiconductor Device Having Three Terminal Miniature Package

(71) Applicant: Texas Instruments Incorporated, Dallas, TX (US)

(72) Inventors: Reynaldo Corpuz Javier, Plano, TX (US); Sreenivasan Koduri, Allen, TX (US)

(21) Appl. No.: 13/939,276

(22) Filed: Jul. 11, 2013

(51) Int. Cl. H01L 23/495; H01L 23/00

(52) U.S. Cl. CPC H01L 23/49575; H01L 23/49568; H01L 24/85
USPC 257/675; 257/676; 438/122

(57) ABSTRACT

A semiconductor device (100) comprises a semiconductor chip (310) attached to the pad (302) of a planar leadframe and connected by bonding wires (411) to two leads (403) of the leadframe. The device further includes a plastic body (130) encapsulating chip and wires, the body shaped as a pentahedron with two sides (101, 102) touching at right angle, opposite body ends formed by parallel planes configured as right-angle triangles. The pad (302) and the two leads (303) are exposed from the plastic surface at one body end in order to be operable as solderable device pins positioned in the corners of the triangle.

### FIELD OF THE INVENTION

The present invention is related in general to the field of semiconductor devices and processes, and more specifically to structures and fabrication method of SON/QFN type devices having three terminals and a miniature package with triangular cross section.

### DESCRIPTION OF RELATED ART

Plastic packages for semiconductor chips of many logic and analog integrated circuit families are often being manufactured with pins arranged in the so-called Small Outline No-lead (SON) or Quad Flat No-lead (QFN) configuration. In these product categories, the packages do not have the traditional cantilevered metal leads, or pointed pins; instead, they have metallic terminals with surfaces flat with the surrounding plastic material so that these terminals can be conveniently connected (for instance by soldering) to contact pads of printed circuit boards (PCBs). The trend of the SON/QFN technology is for shrinking the size of the packages.

Small SON/QFN package designs are constrained by the footprint of the package, the number of pins, and the process limitations as reflected by the layout rules of the leadframe. Leadframes in most SON/QFN packages have rectangle-shaped leads arranged in parallel along the four edges of the package, with one short side of the rectangle near the package edge and the long sides running between the edge and the center. Each lead has some portions of its perimeter half-etched in order to create locks for solid anchoring of the lead in the molding compound. If a chip pad can be accommodated, it usually has a rectangular shape with the four edges parallel to the four edges of the package. The polymeric compound of the plastic packages leave one surface of each lead exposed from the encapsulation for connection to the PCB.

For many applications, such as handheld telephones, portable appliances, cameras, and medical equipments, the scaling of the SON/QFN packages reached an area of only 1 mm by 1 mm. One recently introduced SON/QFN package of this small size features a design with four leads shaped as triangles situated at the four corner locations and a chip pad with edges oriented at 45° with respect to the package edges. The chip pad doubles as thermal pad to spread the operational heat. Another recently introduced SON/QFN product of 1 mm by 1 mm area has six leads with the conventional rectangular shape arranged parallel along two opposite edges of the package. In this product, each lead has a mold lock, which is formed as a half-etched extension of the lead; the extension is formed along the center line of the lead towards the package center. Near the package center, the mold locks of the leads positioned along one edge of the package come close to the mold locks of the respective leads positioned along the opposite package edge. As a consequence, the half-etched mold locks do not leave space for a chip pad; the chip is assembled on the half-etched lead mold locks by an electrically and thermally insulating layer of adhesive polymeric compound.

### SUMMARY OF THE INVENTION

Based on the continuing trends of miniaturizing electronic components while maintaining device functionality and performance, and increasing the number of components attached to a printed circuit board (PCB), a square-shaped QFN/SON-type device with three pins and a side length of 0.6 mm, requiring 0.36 mm² board assembly area, was challenged to be scaled down in dimensions but not performance in order to save board real estate.

Applicants solved the miniaturization problem when they discovered a leadframe arrangement allowing to place the required three pins in a triangular configuration so that the triangle included a right angle and the area of the triangle was one half (0.18 mm²) of the original square-shaped area. The triangle with the right angle is preferably isosceles.

The leadframe is being half-etched so that the pin in the corner of the right angle also serves as the assembly pad for the rectangular semiconductor chip and further is structured as a heat spreader. The chip remains the same as in the original square-shaped package and can be attached to the new pad with a chip side parallel to the hypenuse of the right-angle triangle. The chip terminals are wire bonded to the terminals positioned in the acute corners of the triangle.

When the device is encapsulated in a plastic compound, the surface with the three pins remains un-encapsulated so that the pins are available for solder attachment to the PCB, while the body of the device package is configured as a pentahedron with two sides touching at right angle and opposite body ends forming parallel planes configured as right-angle triangles.

It is a technical advantage that with the package area reduced by 50% and with the triangular shape, the device can be PCB mounted in very tight spaces such as an edge of the PCB.

It is another technical advantage that existing manufacturing processes, equipment and tools can be reused. It is another advantage that the cost of 50% of direct material can be saved.

### BRIEF DESCRIPTION OF THE DRAWINGS

FIG. 1 illustrates a perspective view of a miniature plastic small outline no-lead/quad flat no-lead (SON/QFN) package, shaped as a pentahedron with metallic pins exposed on a right-angle triangular surface.

FIG. 2 shows a bottom view of the package of FIG. 1, depicting the metallic pins exposed on the right-angle triangular surface of the package. perspective view of an exemplary embodiment, a leadframe with pad and leads in right-angle triangular configuration, the pad having a chip attached to the pad with its long side parallel to the hypotenuse of the triangle.

FIG. 3 is an X-ray top view of the leadframe inside the package of FIG. 1, with a chip attached to a pad and bonded with wires to a plurality of leads, illustrating the half-etch configuration of the base metal to provide a heat spreader and mold locks.

FIG. 4A illustrates a perspective top view of the leadframe of FIG. 3, with pad and leads in right-angle triangular configuration; the pad has a semiconductor chip attached with the chip's its long side parallel to the hypotenuse of the triangle and with the chip's terminals wire-bonded to the leads.

FIG. 4B illustrates a perspective bottom view of the leadframe of FIG. 3, with pad and leads in right-angle triangular configuration; the pad has a semiconductor chip attached with the chip's its long side parallel to the hypotenuse of the triangle and with the chip's terminals wire-bonded to the leads. The half-etched leadframe shows the pins and the mold locks.

### DETAILED DESCRIPTION OF THE PREFERRED EMBODIMENTS

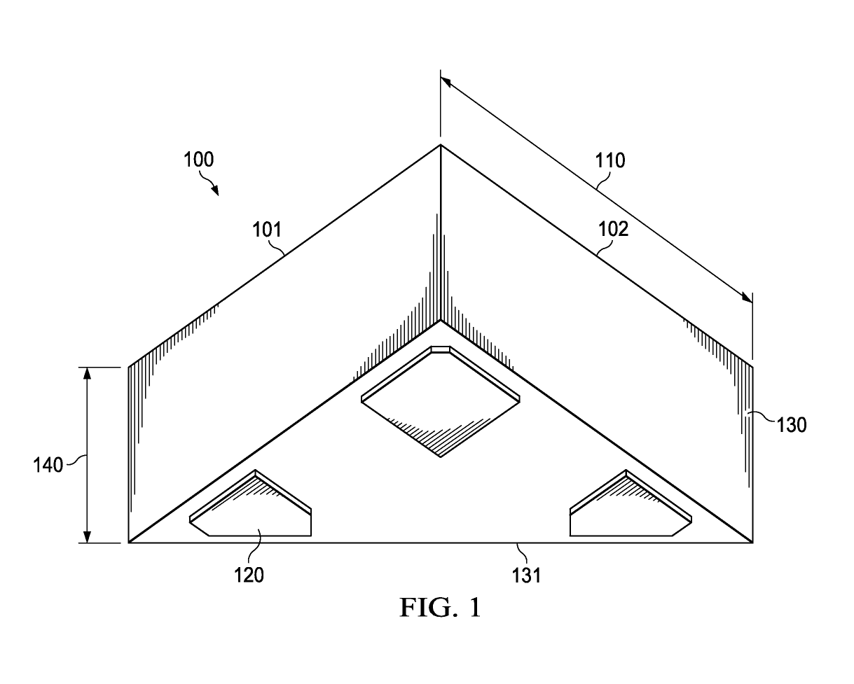

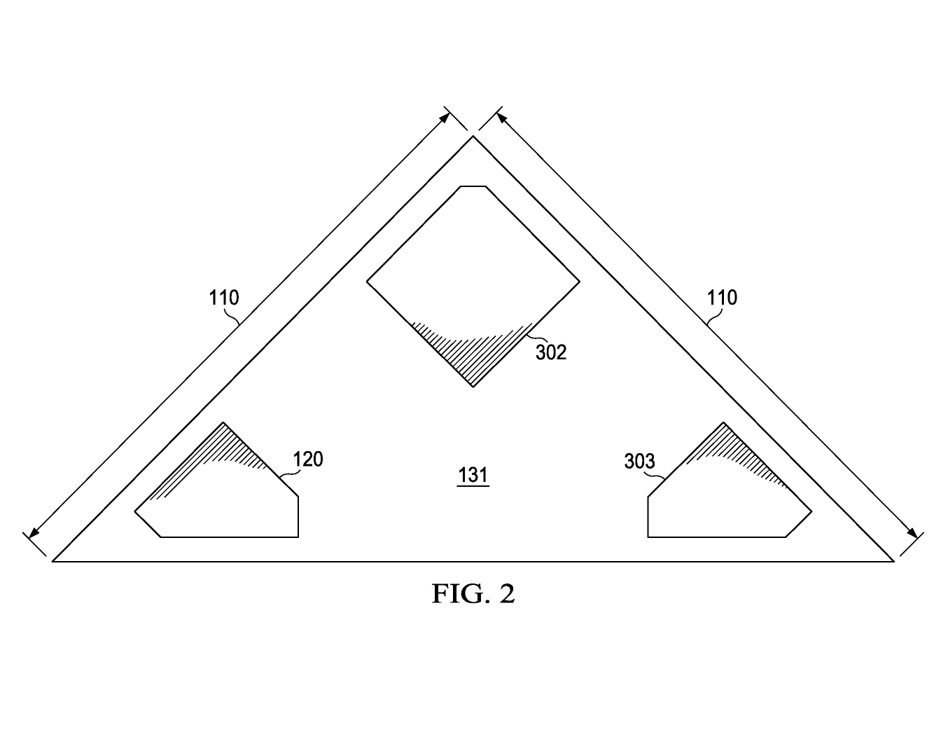

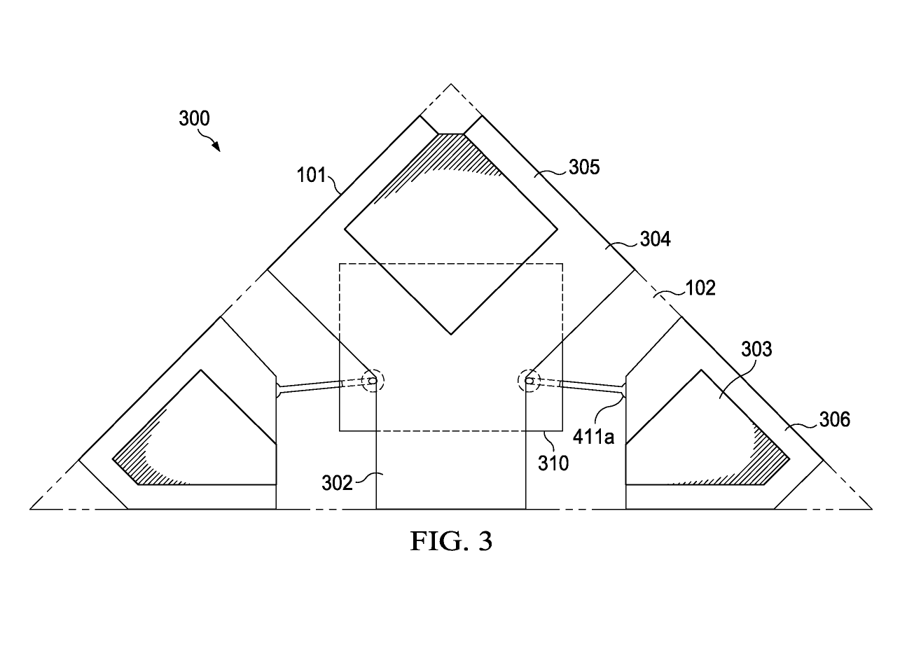

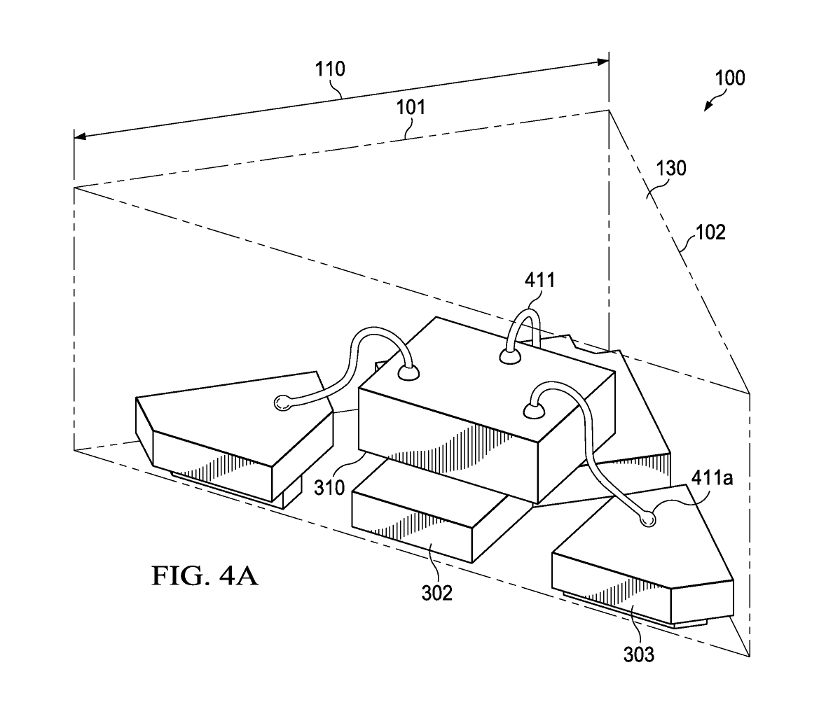

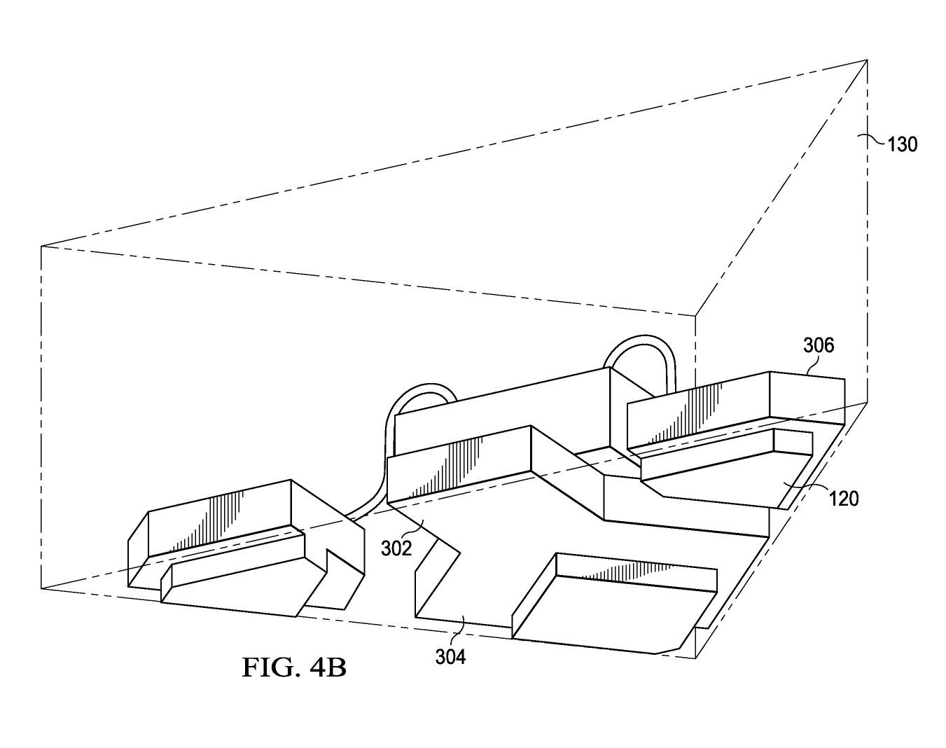

FIG. 1 illustrates a perspective view, and FIG. 2 shows a bottom view, of an exemplary embodiment of a miniature device generally designated 100. The package of the device uses a plastic polymeric compound 130 to encapsulate an assembly of a semiconductor chip on a leadframe (shown in FIGS. 3, 4A and 4B). On the bottom surface 131 of the package, metallic pins 120 are un-encapsulated and available for attachment of the device to externals parts. Since the package terminals are not shaped as conventional cantilevered leads, but flat metal pins 220, the embodiment is classified as a plastic Small Outline No-lead (SON) package, frequently also called a Quad Flat No-lead (QFN) package.

It should be noted that herein, following widespread usage, package terminals 120 are referred to as pins, in spite of the fact that they have a flat surface and do not resemble pointed objects such as nails. When a leadframe is used for an embodiment to assemble a semiconductor chip on the leadframe pad and connect the chip input/output terminals to the leadframe leads, those leads are herein also referred to as pins. The metal pins may be coplanar with the surrounding plastic surface, or they may protrude a step of about 0.05 mm from the plastic surface.

The plastic polymeric package of the embodiment of FIG. 1 is shaped as a pentahedron. Of the pentahedron's five plane surfaces, the two surfaces designated 101 and 102 touch each other at right angle. Consequently, surface 131 and the opposite surface (not shown in FIG. 1) are configured as right-angle triangles. In other embodiments, the angle may be less or more than 90°. The height 140 of the package is determined by the encapsulated height of the arc formed by bonding wires (see FIG. 4). In the pentahedron of FIG. 1, the planes of plastic surface 131 (with the metallic pins 120) and the opposite plastic surface, not shown in FIG. 1, are parallel. The side length 110 of the exemplary pentahedron of FIG. 1 is 0.6 mm, which justifies the classification of device 100 as a miniature device.

In FIG. 2, the side length indicated for the package bottom 131 is the same as the side length 110 shown in FIG. 1. Furthermore, as indicated in FIG. 2, the side length 110 is the same for both sides of the right-angle triangle. For the depicted example, side length 110 is 0.6 mm. Consequently, the outline of the package bottom 131 is an isosceles triangle. Alternatively, the triangle of the package bottom of other packages may not be isosceles, or not be right-angle; an example is a package bottom shaped as an equilateral triangle. Exposed form the surface 131 of the plastic compound of package are three metal pins generally designated 120. In this example, the pins in the triangle corners with an acute angle have an approximately triangular shape, while the pin in the right-angle corner has approximately square shape. In other embodiments, these shapes may be different and the pin sizes may be different. As shown in FIG. 3, attached to each pin is at least one mold lock. Furthermore, it is preferred that the surface of pins 220 has a metallurgical composition suitable for solder attachment to external parts. As an example, for pins made of a base metal including copper, the surface of pins 120 may have a layer of nickel on the base metal; the nickel in turn may be covered by a thin layer of palladium or gold to protect the nickel against any oxidation.

The exemplary package 100 encapsulates a leadframe for assembling a semiconductor chip. Referring now to FIG. 3, an exemplary leadframe generally designated 300 is depicted in an X-ray top view with the chip attached and wire bonded. The structural elements of leadframe 300 include a chip assembly pad 302 and two leads 303. As FIG. 3 shows, the leadframe portions are positioned in triangular configuration with the assembly pad preferably in the middle and the two leads on opposite sides of the pad. Furthermore, the portions have an outline such that outline together with position result in a right-angle triangle, and further, in the example of FIG. 3, in an isosceles triangle. Preferably, pad 302 is close the corner of the right angle and leads 103 are in the corners of the cute angles.

The preferred base metal for the leadframe in FIG. 3 is copper or a copper alloy. Base metal alternatives include brass, aluminum, iron-nickel alloys (for instance the so-called Alloy 42), and Kovar™. Typically, the leadframe originates with a metal sheet with a preferred thickness in the range from about 100 to 300 μm; thinner sheets are possible. If needed, the ductility in this thickness range provides the 5 to 15% elongation that facilitates an intended bending and forming operation. The configuration or structure of the leadframe is stamped or etched from the starting metal sheet.

As defined herein, the starting material of the leadframe is called the “base metal”, indicating the type of metal. Consequently, the term “base metal” is not to be construed in an electrochemical sense (as in opposition to “noble metal”) or in a structural sense.

FIG. 3 indicates that the prime function provided by pad 302 is the assembly and adhesive attachment of chip 310; the prime function of leads 303 is the attachment of wire stitch bonds 411a. In addition, the structural elements are half-etched in order to be shaped for additional functions. Pad 302 is half-etched to operate as thermal heat spreader 304 and to offer mold locks 305. Leads 303 are half-etched with rims 306 protruding from the leads to operate as mold locks.

A mold lock stabilizes the pin to which it is attached so that the pin cannot move in x-, y-, or z-direction; consequently, the pin is locked in all three dimensions. The outline of a mold lock is designed to prevent pin movements in the x- and y-dimensions; for preventing a movement in the z-direction, the metal sheet is locally thinned by partial etching so that molding compound can cover the lock area during the encapsulation process; the hardened compound inhibits a pin movement in the z-direction. Partially etched leadframe portions, such as the mold locks, are commonly referred to as half-etched leadframe portions. (In FIG. 3, the half-etched mold locks are hidden under the molding compound and are thus depicted by shaded outlines.)

FIG. 4A illustrates a perspective top view of a device 100 with the leadframe of FIG. 3 encapsulated by plastic packaging compound 130. The leadframe shows pad 302 and leads 303 in right-angle triangular configuration. Pad 302 has a semiconductor chip 310 attached with the chip's its long side parallel to the hypotenuse of the triangle and with the chip's terminals wire-bonded to the leads. Semiconductor chip 310 may be made of silicon, silicon germanium, gallium nitride, gallium arsenide, or any III-V or II-IV compound used for semiconductor devices. Chip 310 preferably has bond pads with metallization suitable for gold ball or copper ball bonding; the surface of the bond pads may thus preferably be aluminum, gold, palladium, or pure copper. Chip 310 is attached to chip pad 302 using adhesive material (typically an epoxy or polyimide which has to undergo polymerization). In many products such as the example of FIG. 4A, chip 310 has a relatively large size compared to the size of the leadframe. It is therefore advantageous, as FIG. 4 shows, to assembly a rectangular chip, such as chip 310 in FIGS. 3, 4A and 4B, with its long side parallel to the hypotenuse of the right-angle triangle of the leadframe.

The electrical interconnections 411 shown in FIG. 4A are preferably gold wires or copper wires spanning the gap between chip bond pads and leads. The preferred bonding technique is ball bonding with the ball attached to the pad; alternatives include ribbon bonding and wedge bonding. Due to high electrical conductivity, copper wires are preferably in the diameter range from about 10 to 25 μm; thicker and thinner wire diameters have been used. When alternatively wire 411 is made of gold or aluminum, wire diameters are preferably between about 15 and 30 μm. The contact of wire 411 to lead 303 is provided by stitch bonds 411a. For reliable bonding, stitch bonds are preferably welded to a thin layer of a noble metal (such as silver, palladium or gold) spot plated on the leadframe base metal.

FIG. 4B shows a perspective view of the bottom of the miniature package encapsulating chip and wires assembled on the leadframe in a plastic polymeric material 130. FIG. 4B depicts the result of the half-etching process of the base metal sheet of the leadframe. Flat metal pins 120 show the original plane of the metal sheet, and the half-etched recesses indicate the mold locks 304 and 306; also created by half-etching is the assembly pad 302, which is seized to operate as a thermal heat spreader. As FIG. 4B illustrates, pins 120 are preferably coplanar with the surrounding plastic surface.

Another embodiment of the invention is a method for fabricating a miniature three-terminal plastic packaged device. In the first step, a planar leadframe is provided, which includes an assembly pad and two leads arranged in the corners of a triangle. Preferably, the triangle is a right-angle triangle; in this case, the pad is preferably positioned near the corner of the right angle and the leads are placed in the corners of the acute angles. The lead surfaces intended to be enclosed in the packaging compound preferably have a metallurgical surface configuration to allow reliable stitch bonding, such as a spot of a noble metal like silver, gold, or palladium. The lead surfaces intended to remain un-enclosed by packaging compound preferably have a metallurgical surface configuration to allow reliable soldering, such as a layer of nickel, tin, or palladium. Preferably, the leadframe is half-etched to create rims protruding from pad and leads, which operate as mold locks; in addition, half-etching creates an extension from the pad, which can operate as thermal spreader.

In the next process step, a semiconductor chip is attached to the leadframe pad, preferably by an adhesive polymeric compound. Next, the chip terminals are connected to the leads. When wire bonding is employed, the ball bonds are preferably formed on the chip terminals, which have a metallurgical surface configuration to serve a bond pads. As stated, the stitch bonds are formed on the leads.

In the next process step, the chip and the wires are encapsulated in a plastic body shaped as a pentahedron having two sides touching at right angle. The plastic body leaves the pad surface opposite to the chip and the lead surfaces opposite the stitch bonds un-encapsulated. As a consequence, the plastic body has a surface with exposed pins in triangular arrangement.

While this invention has been described in reference to illustrative embodiments, this description is not intended to be construed in a limiting sense. Various modifications and combinations of the illustrative embodiments, as well as other embodiments of the invention, will be apparent to persons skilled in the art upon reference to the description. As an example, the invention applies not only to SON/QFN packages with side lengths of 0.6 mm, but to packages with scaled dimensions, especially to packages with smaller side lengths.

As another example, the concept of a small plastic SON/QFN package with three pins and a thermal pad for high power operation can be applied to packages, which are pentahedron-shaped with a triangular cross section of angles other than right angle.

In yet another example, the material and the thickness of the metal leadframe can be selected as a function of the size of the chip so that specific product goals of the assembled package can be achieved such as final thickness, mechanical strength, minimum warpage, prevention of cracking, strong symbolization contrast, compatibility with pick-and-place machines, and minimum electrical parasitics. In addition, the starting metal of the plate may be roughened, or plated with metal layers (such as nickel, palladium, gold, and tin), to improve adhesion to polymeric compounds and solderablity to PCBs.

It is therefore intended that the appended claims encompass any such modifications or embodiments.

1. A semiconductor device comprising:
a semiconductor chip attached to the pad of a planar leadframe and wire-bonded to two leads of the leadframe;
a plastic body encapsulating chip and wires, the body shaped as a pentahedron with two sides touching at right angle, opposite body ends formed by parallel planes configured as right-angle triangles; and
the pad and the two leads exposed from the plastic surface at one body end to be operable as device pins positioned in the corners of the triangle.

2. The device of claim 1 wherein the right-angle triangle is an isosceles triangle.

3. The device of claim 1 wherein each pin further includes a mold lock protruding from the pin.

4. The device of claim 3 wherein the locks are shaped as rims projecting along the pin edges.

5. The device of claim 1 wherein the pin located in the corner of the right angle is sized as the chip assembly pad suitable for orienting the attached chip with a side parallel to the hypotenuse of the triangle.

6. The device of claim 5 wherein the pin located in the corner of the right angle further includes an extension suitable as thermal heat spreader.

7. A method for fabricating a device comprising the steps of:
providing a planar leadframe including a pad and two leads arranged in the corners of a right-angle triangle;
attaching a semiconductor chip to the pad;
wire-bonding the chip to the leads; and
encapsulating chip and wires in a plastic body shaped as a pentahedron having two sides touching at right angle, the body leaving the surface of the pad and the leads un-encapsulated, thus bestowing to the device a plastic surface with exposed pins in triangular arrangement.

8. The method of claim 7 wherein each pin further includes a mold lock protruding from the pin.

9. The method of claim 8 wherein the locks are shaped as rims projecting along the pin edges.

10. The method of claim 7 wherein the pin located in the corner of the right angle is sized as the chip assembly pad suitable for orienting the attached chip with a side parallel to the hypotenuse of the triangle.

11. The method of claim 10 wherein the pin located in the corner of the right angle further includes an extension suitable as thermal heat spreader.
